(19) United States
(12) Patent Application Publication
(10) Pub. No.: US 2025/0248055 A1
(43) Pub. Date: Jul. 31, 2025

(54) STRUCTURE WITH CAPACITIVE JUNCTION BETWEEN SILICIDE LAYER AND ELECTRODE AND RELATED METHOD

(71) Applicant: GlobalFoundries Singapore Pte. Ltd., Singapore (SG)

(72) Inventors: Bong Woong Mun, Singapore (SG); Jeoung Mo Koo, Singapore (SG)

(21) Appl. No.: 18/428,035

(22) Filed: Jan. 31, 2024

(51) Int. Cl. H01L 21/3205; H01L 21/762; H01L 21/768; H01L 23/522; H01L 23/528; H01L 27/06

(52) U.S. Cl. CPC H10D 1/692; H01L 21/32053; H01L 21/76224; H01L 21/76877; H01L 23/5226; H01L 23/528; H10D 84/811

(57) ABSTRACT

Embodiments of the disclosure provide a structure and related method for a capacitive junction between a silicide layer and an electrode. A structure of the disclosure includes a silicide layer on a substrate. A dielectric layer is over the substrate and the silicide layer. An electrode is within a wiring layer on the dielectric layer. The dielectric layer defines a capacitive junction between the silicide layer and the electrode.

### BACKGROUND

The present disclosure relates to integrated circuit structures and, more particularly, to a structure and related method to provide a capacitive junction between a silicide layer and an electrode.

Capacitors are used in a wide variety of integrated circuits (ICs). As ICs have scaled smaller, forming capacitors has become more challenging. Some capacitors may be used to provide galvanic isolation between active device components, i.e., an electrical coupling that prevents passage of direct current (DC) but allows passage of alternating current (AC) from one terminal to another. Conventional structures and processes to provide capacitor-based galvanic isolation have been limited by the available thickness of conventional dielectric materials, and hence the level of isolation is similarly limited. Conventional capacitor-based galvanic isolation structures are thus insufficient for accommodating relatively high voltage levels.

### SUMMARY

All aspects, examples and features mentioned below can be combined in any technically possible way.

An aspect of the disclosure provides a structure including: a silicide layer on a substrate; a dielectric layer over the substrate and the silicide layer; and an electrode within a wiring layer on the dielectric layer, wherein the dielectric layer defines a capacitive junction between the silicide layer and the electrode.

An aspect of the disclosure includes a structure, including: a substrate including a recessed region adjacent a non-recessed region; a silicide layer within the recessed region of the substrate; a dielectric layer over the silicide layer, wherein the dielectric layer includes: a recess isolation (TI) on the silicide layer and within the recessed region of the substrate, and an inter-level dielectric (ILD) on the TI; and an electrode within a wiring layer on the dielectric layer, wherein the dielectric layer defines a capacitive junction between the silicide layer and the electrode.

An aspect of the disclosure includes a method, including: forming a silicide layer on a substrate; forming a dielectric layer over the substrate and the silicide layer; and forming an electrode within a wiring layer on the dielectric layer, wherein the dielectric layer defines a capacitive junction between the silicide layer and the electrode.

Two or more aspects described in this disclosure, including those described in this summary section, may be combined to form implementations not specifically described herein.

The details of one or more implementations are set forth in the accompanying drawings and the description below. Other features, objects and advantages will be apparent from the description and drawings, and from the claims.

### BRIEF DESCRIPTION OF THE DRAWINGS

The embodiments of this disclosure will be described in detail, with reference to the following figures, wherein like designations denote like elements, and wherein:

FIG. 1 shows a cross-sectional view of a structure according to embodiments of the disclosure.

FIG. 2 shows a plan view of a structure according to embodiments of the disclosure.

FIG. 3 shows a cross-sectional view of a structure according to embodiments of the disclosure adjacent active devices.

FIG. 4 shows a cross-sectional view of a structure according to further embodiments of the disclosure.

FIG. 5 shows a plan view of a structure according to embodiments of the disclosure.

FIG. 6 shows a cross-sectional view of a structure according to further embodiments of the disclosure adjacent active devices.

FIG. 7 shows a cross-sectional view of a structure according to still further embodiments of the disclosure.

FIG. 8 shows a plan view of a structure according to still further embodiments of the disclosure.

FIG. 9 shows a cross-sectional view of a structure according to still further embodiments of the disclosure adjacent active devices.

FIG. 10 shows an illustrative flow diagram of a method according to embodiments of the disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (a) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

Embodiments of the disclosure provide a structure with a capacitive junction between a silicide layer and an electrode, and a related method. A structure of the disclosure includes a silicide layer on a substrate. A dielectric layer is over the substrate and the silicide layer. An electrode is within a wiring layer on the dielectric layer. The dielectric layer defines a capacitive junction between the silicide layer and the electrode. The capacitive junction may provide galvanic isolation between two parts of a device, thus permitting flow of alternating current (AC) signals while preventing passage of direct current (DC) signals. Notably, embodiments of the disclosure may use portions of an inter-level dielectric (ILD) material or other extant areas of isolation to provide a capacitive junction. Through embodiments of the disclosure, a circuit fabricator can omit one or more conventional capacitor structures on a device layer and/or wiring layer, as well as any intermediate isolating or intercoupling components that would otherwise be needed to provide the desired operational characteristics.

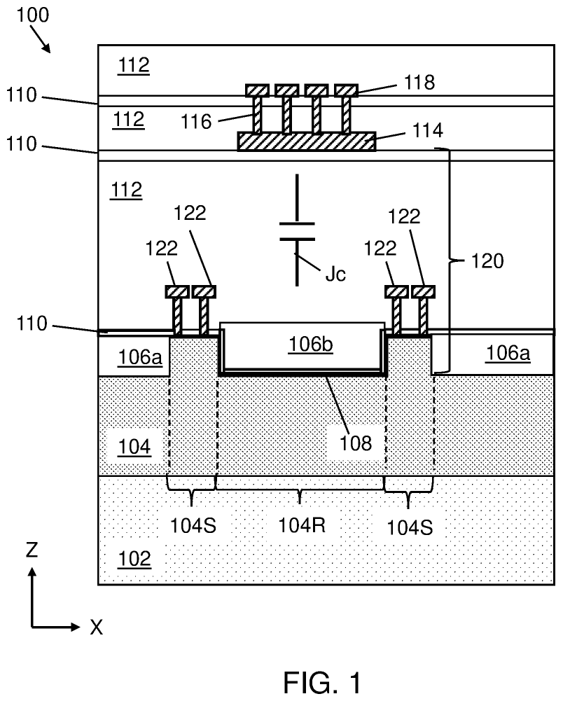

Turning to the drawings, FIG. 1 depicts a cross-sectional view of a structure 100, e.g., to provide galvanic isolation within an integrated circuit (IC) product. Structure 100 may be on a substrate 102 including, e.g., one or more semiconductor materials. Substrate 102 may include but is not limited to silicon, germanium, silicon germanium (SiGe), silicon carbide (SiC), or any other common IC semiconductor substrates. In the case of SiGe, the germanium concentration in substrate 102 may differ from other SiGe-based structures described herein. A portion or entirety of substrate 102 may be strained, and/or may be doped to any desired polarity or concentration. In addition, some portions of substrate 102 may be doped to provide one or more doped wells 104, e.g., for other device structures on substrate 102 not explicitly shown or discussed herein.

Doped well 104 may have the same or similar semiconductor materials as substrate 102 but may have different conductivity through the use of doping. Doped well 104 thus may be considered to be a doped portion of substrate 102. Doping generally refers to a process by which foreign materials (“dopants”) are added to a semiconductor structure to alter its electrical properties, e.g., resistivity and/or conductivity. Where a particular type of doping (e.g., p-type or n-type) doping is discussed herein, it is understood that an opposite doping type may be implemented in alternative embodiments. Implantation, where applicable, refers to a doping process in which ions are accelerated toward a solid surface to penetrate the solid up to a predetermined range based on the energy of the implanted ions. Doping also may be implemented by epitaxially growing different conductivity type semiconductor materials in contact with each other, i.e., in-situ doping during epitaxy.

Structure 100 also may include one or more trench isolation layers (TI(s)) 106. TI(s) 106 may be made by forming and filling recesses (not labeled) with an insulating material such as oxide. Some TI(s) 106a may separate substrate 102 and/or doped well 104 from other active components not formed thereon or connected thereto. As discussed herein, one or more TI(s) 106b may instead provide dielectric material for galvanic isolation, i.e., a layer of dielectric between oppositely charged conductive materials within structure 100. Various portions of structure 100, including oppositely charged conductive materials, dielectric materials, contacts, and/or other devices, where applicable, may be formed on doped well 104, including portions of doped well 104 that are covered by TI(s) 106b. TI(s) 106a, 106b may be differentiated from each other solely based on their function and/or position in structure 100, as well as whether any conductive materials (e.g., silicide layer(s) 108) are present between doped well 104 and TI(s) 106b thereover. TI(s) 106a are not on silicide layer(s) 108, whereas TI(s) 106b are on silicide layer(s) 108. TI(s) 106 may be formed before other portions of structure 100, including adjacent device components, are formed over substrate 102 but this is not necessarily true in all implementations. Portions of doped well 104 below TI(s) 106b define recessed regions 104R of doped well 104, whereas portions of doped well 104 not below TI(s) 106b define non-recessed regions 104S of doped well 104. The upper surface of non-recessed region(s) 104S is above the upper surface of recessed region(s) 104R, and thus each region 104R, 104S may be differentiated by the positions of their upper surfaces.

Embodiments of structure 100 include silicide layer 108 on substrate 102, e.g., on upper surfaces and sidewalls of doped well 104. Silicide layer 108 may be formed on or within portions of doped well 104, e.g., by providing a conductive metal such as cobalt (Co), titanium (Ti), nickel (Ni), platinum (Pt), or similar material on the upper surface(s) of a targeted material. The conductive metal(s) may be formed selectively on doped well 104, and optionally may be formed after TI(s) 106a are formed but before TI(s) 106b are formed within doped well 104. The conductive material may be annealed while in contact with the underlying semiconductor (e.g., substrate 102 and/or doped well 104) to produce silicide layer 108, which includes semiconductor material together with the annealed conductor, thus creating a material of higher conductivity than doped well 104. Excess conductive material can then be removed using any now known or later developed solution, e.g., etching.

The forming of silicide layer 108 may be implemented after forming a targeted recess within substrate 102 and/or doped well 104, but before the forming of TI(s) 106b within the targeted recess. Silicide layer 108 is located on the upper surface of recessed regions 104R of doped well 104 but contacts the upper surface and sidewalls of non-recessed regions 104S. Thus, silicide layer 108 will interface with uppermost surfaces of substrate 102 and/or doped well 104 and will also correspond to the geometry of the recess where TI(s) 106b is/are formed.

As shown in FIG. 1, at least part of silicide layer 108 may be substantially U-shaped. Silicide layer 108 may not be formed beneath other TI(s) 106a at the boundary of structure 100, e.g., to maintain electrical isolation between structure 100 and any adjacent portions of the same device.

Structure 100 may include an insulative film 110 (e.g., silicon nitride (SiN), other nitride based insulators, and/or other insulative materials capable of serving as an etch stop layer) on doped well 104, STI(s) 106a, and on silicide layer 108 such that insulative film 110 is located between silicide layer 108 and TI(s) 106b. Insulative film 110 may be formed by deposition and/or other processes to non-selectively provide insulative materials to a desired thickness, such that insulative film 110 does not fill recessed portions of doped well 104 where TI(s) 106b will be formed.

An inter-level dielectric (ILD) layer 112 may be over TI(s) 106a, 106b, and insulative film 110. ILD layer 112 may include the same insulating material as TI(s) 106a, 106b or may include a different electrically insulative material for vertically separating active materials from overlying materials, e.g., various horizontally extending wires or vias. ILD layer 112 and TI(s) 106a, 106b nonetheless constitute different components, e.g., due to TI(s) 106a, 106b being vertically between doped well 104 and any other components thereon. ILD layer 112 may be formed by deposition and/or other techniques to provide electrically insulating materials, and can then be planarized (e.g., using CMP).

An additional insulative film 110 may be on ILD layer 112, e.g., to provide an etch stop layer vertically between distinct wiring layers of a device. Another ILD layer 112 may be on insulative film 110. Yet another insulative film 110 may be on the overlying ILD layer 112, and yet another ILD layer 112 may be on insulative film 110. This arrangement of ILD layers 112 alternating with insulative films 110 provides a set of distinct metal wiring layers in which insulative films 110 provide “etch stop” materials to enable processing and forming of individual layers, as generally known in the art. Embodiments of structure 100 may incorporate ILD layer 112 and/or other insulative materials into a capacitive structure to provide galvanic isolation between different components.

An electrode 114 may be within any wiring layer located over silicide layer 108 in structure 100. According to an example, electrode 114 may be on insulative film 110 and within ILD layer 112 that is directly over ILD layer 112 in which silicide layer 108 is formed. Electrode 114 may include any currently known or later developed conductive metal suitable to accumulate charge across a dielectric junction, e.g., tungsten (W), titanium (Ti), ruthenium (Ru), cobalt (Co), copper (Cu), aluminum (Al), etc. Electrode 114 may be formed by depositing conductive materials on insulative film 110 and/or ILD layer 112, e.g., by application of damascene processes to form horizontal and vertical conductive metal layers as discussed herein. Although silicide layer 108 is not explicitly referred to as an “electrode” herein, silicide layer 108 will function as a complementary electrode for electrode 114 when a voltage is applied to electrode 114 and/or silicide layer 108 during operation. One or more vias 116 optionally may couple electrode 114 to other metal wiring levels. In this case, one or more metal wires 118 in another wiring layer may be formed on, and coupled to, via(s) 116. Sidewalls of electrode 114, vias 116, and/or metal wires 118 may include refractory metal liners (not shown for simplicity of illustration) including, for example, ruthenium (Ru), tantalum (Ta), titanium (Ti), tungsten (W), iridium (Ir), rhodium (Rh) and platinum (Pt), etc., or mixtures of thereof.

TI(s) 106b, ILD layer(s) 112, insulative film(s) 110, and/or portions thereof together may define a dielectric layer 120 between silicide layer 108 and electrode 114. Embodiments of structure 100 differ from conventional integrated circuit capacitor structures (e.g., metal-insulator-metal (MIM) capacitors) by using silicide layer 108 in place of another electrode in a device layer and/or wiring layer. In a conventional device, the insulation and/or thickness of ILD layer 112 alone may not be sufficient to provide a capacitive junction, or sufficient capacitance for galvanic isolation between active components of a device. In structure 100, dielectric layer 120 defines a capacitive junction Jc between silicide layer 108 and electrode 114. Applying a voltage differential across silicide layer 108 and electrode 114 will induce an electric field across capacitive junction Jc, thereby accumulating a net charge on either silicide layer 108 or electrode 114 (depending on voltage polarity). During operation, capacitive junction Jc between silicide layer 108 and electrode 114 will permit passage of alternating current (AC) signals but will prevent direct current (DC) signals from passing (i.e., due to the presence of dielectric layer 120). Thus, structure 100 may be implemented for galvanic isolation between various active components of a product.

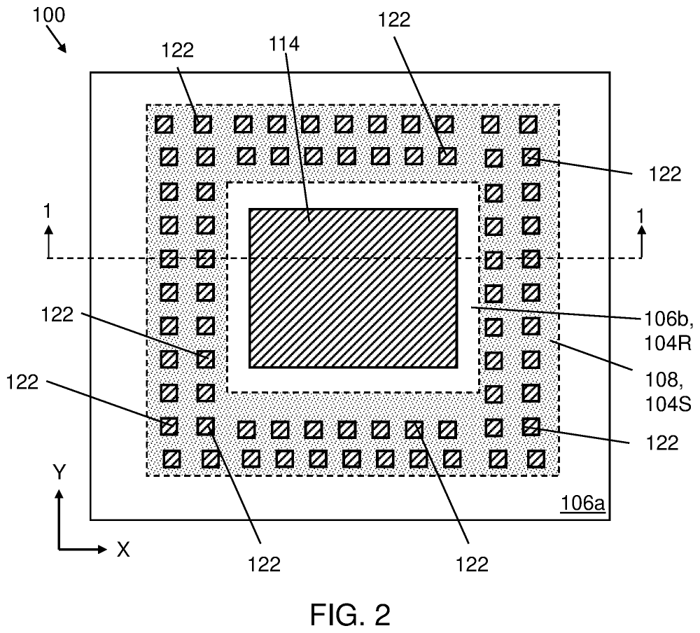

Referring to FIGS. 1 and 2 together, structure 100 may include other components to provide electrical intercoupling to other components. Similar to electrode 114, silicide layer 108 may be coupled to other structures and devices through its own set of coupling components (e.g., conductive contacts, wires, vias, etc.). Silicide layer 108 being relatively thin as compared to electrode 114, in some cases, may require a relatively larger number of conductive couplings to be formed thereon. One or more contacts 122 may extend at least partially through ILD layer 112 to silicide layer 108, and in some cases, may be located over non-recessed region 104S of doped well 104 and/or substrate 102. The cross-section shown in FIG. 1 illustrates four contacts 122, but any number of contacts 122 are possible. Each contact 122 may connect to other devices, metal wires, vias, etc., by extending through ILD layer 112 into or out of the plane of the page. In alternative embodiments, contacts 122 may extend completely through ILD layer 112 over silicide layer 108 to one or more overlying metal wiring layers. Where silicide layer 108 is substantially thinner than electrode 114, a larger number of contacts 122 will improve the function of silicide layer 108 as a capacitive electrode by providing more conductive pathways for current to flow through silicide layer 108.

In the plan view of FIG. 2, a substantial number (e.g., seventy-two) contacts 122 are on silicide layer 108 and arranged to surround recessed region 104R of doped well 104. The total number of contacts 122 can be customized based on the size (e.g., thickness, surface area in plane X-Y) of silicide layer 108, thickness of dielectric layer 120, and/or other attributes of structure 100. Where contacts 122 are over non-recessed region 104S, portions of silicide layer 108 vertically aligned with electrode 114 may be over recessed region 104R to provide a larger amount of dielectric material in capacitive junction Jc. In further implementations, electrode 114 also may be over non-recessed regions 104S of doped well 104.

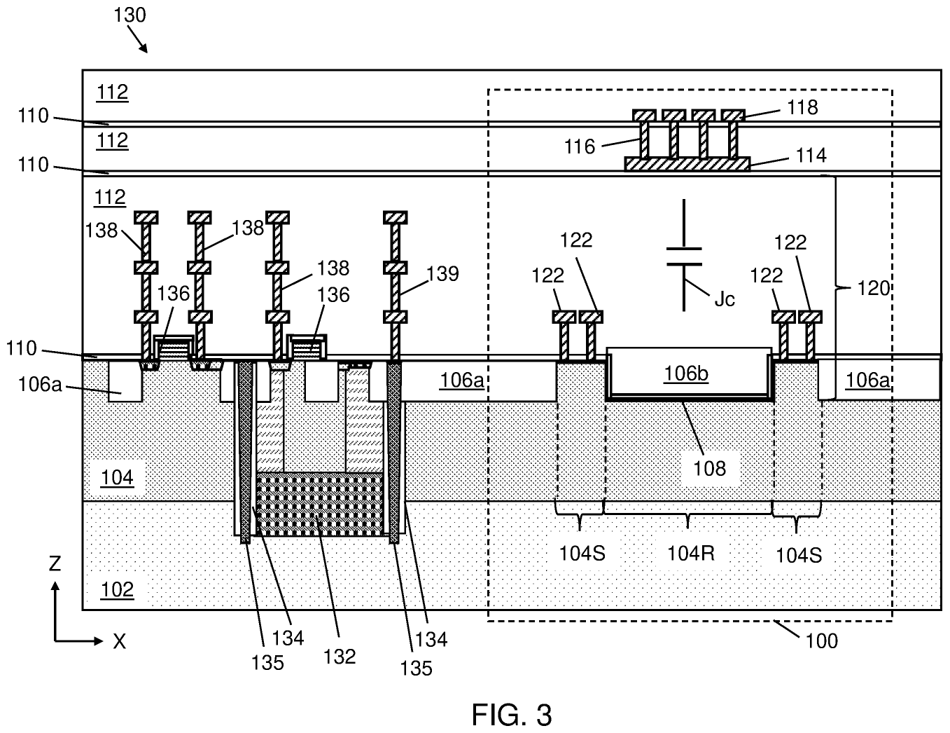

FIG. 3 depicts a cross-sectional view of an integrated circuit (IC) structure 130 including an embodiment of structure 100 therein. Structure 100, during operation, may provide galvanic isolation between various components formed on substrate 102. As discussed elsewhere herein, one or more TI(s) 106a may not be integrated into dielectric layer 120 and may horizontally separate structure 100 from other active device components. In a portion of IC structure 130 located adjacent structure 100, a deep well 132 may be within substrate 102 and/or doped well 104 (e.g., to enable back-biasing of transistors or other devices). Deep well 132 may have a different conductivity type from that of doped well 104 or may have a different doping concentration. A set of deep trench isolations (DTIs) 134 may be adjacent to, and/or may surround deep well 132. In some cases, deep terminals 135 (e.g., doped conductive semiconductor materials having a desired conductivity type) may extend through DTI(s) 134 to allow electrical grounding of substrate 102, and/or other types of connections. One or more active devices 136, e.g., transistors (illustrated by example as metal oxide semiconductor field effect transistors (MOSFETs) or laterally diffused MOSFETs), may be over substrate 102, doped well 104, and/or deep well 132 where desired. Other active devices 136 may include, e.g., capacitors, inductors, resistors, diodes (including electrostatic discharge (ESD) protective diode structures), etc. The various subcomponents of active devices 136 are generally understood in the art and thus not discussed in further detail. A set of device contacts 138 (e.g., source/drain contacts, gate contacts, etc. as known in the art) may extend through ILD layer 112 to various portions of active devices 136 to provide desired electrical connections. One or more grounding contacts 139 may be coupled to substrate 102 through deep terminal(s) 135 to further isolate active devices 136 from other portions of IC structure 130. Active devices 136 may provide, e.g., logic, memory, and/or any other conceivable device components for operating IC structure 130.

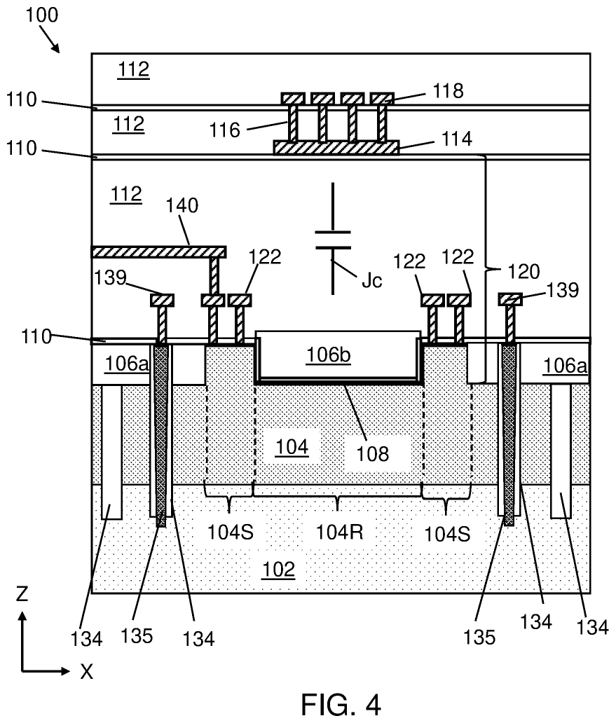

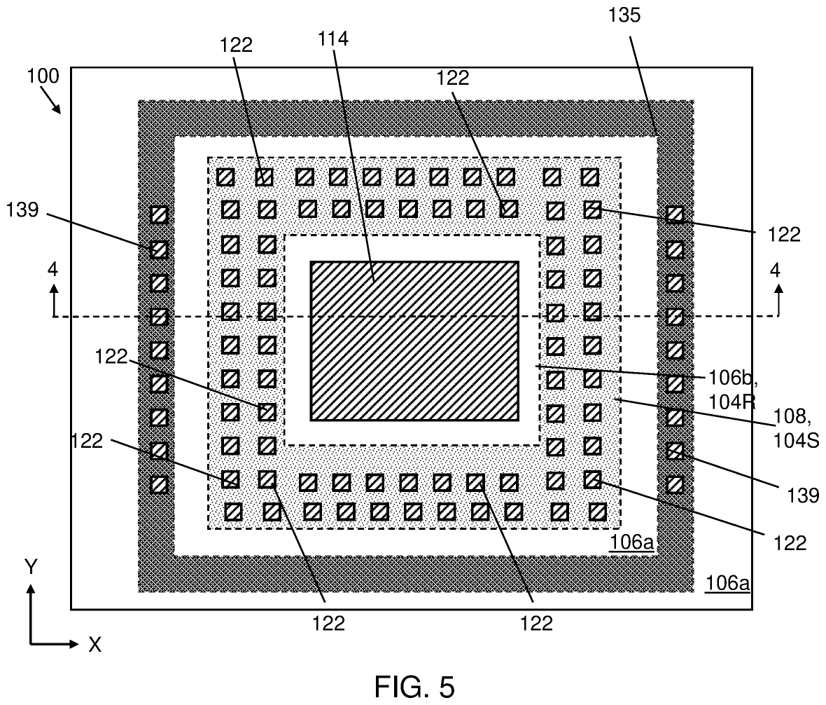

Referring now to FIGS. 4 and 5, further embodiments of structure 100 may include DTIs 134 and further components for grounding and/or isolation within substrate 102 and/or doped well 104. For example, TI(s) 106a adjacent non-recessed regions 104S of doped well 104 may include DTIs 134 therein. Some DTIs 134 also may include deep terminal(s) 135 to substrate 102. Although two DTIs 134 are shown in FIG. 4, these may represent two parts of the same, looped DTI 134 surrounding non-recessed region 104S and recessed region 104R of doped well 104. Optionally, grounding contacts 139 may be on deep terminal(s) 135 to maintain a zero voltage within substrate 102 below silicide layer 108. In various alternative embodiments (e.g., where a floating terminal is desired in substrate 102), grounding contacts 139 may not be present. One or more additional DTIs 134 may surround other DTIs 134, and optionally, may not include deep terminals 135 therein and/or grounding contacts 139 thereon.

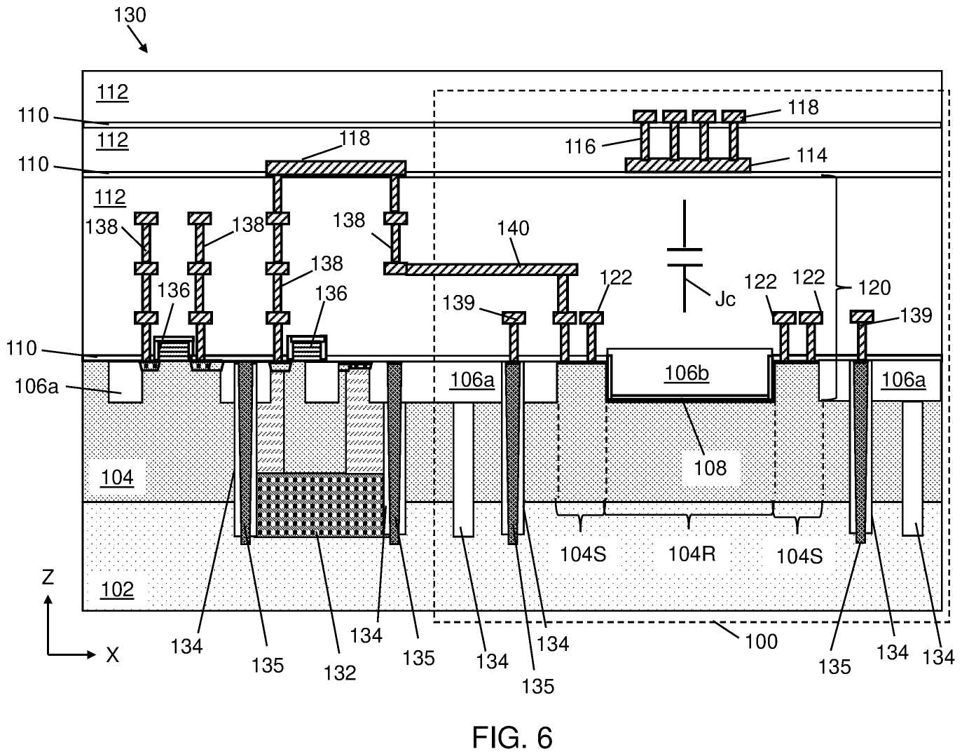

Referring to FIGS. 4 and 6, further optional features of an electrode wire 140 passing horizontally through ILD layer 112 between silicide layer 108 and other portions of a device, are shown. In some cases, electrode wire 140 may couple structure 100 to one or more of active devices 136 (e.g., through metal wire(s) 118, device contacts 138, and/or various other conductive couplings). Electrode wire 140 may be included in structure 100, e.g., to transmit AC signals to or from capacitive junction Jc. Electrode wire 140 for coupling silicide layer 108 also may be present in embodiments of structure 100 without DTI(s) 134 and/or grounding contact 139. In still further embodiments, some electrode wires 140 may couple active device(s) 136 to electrode 114 instead of silicide layer 108.

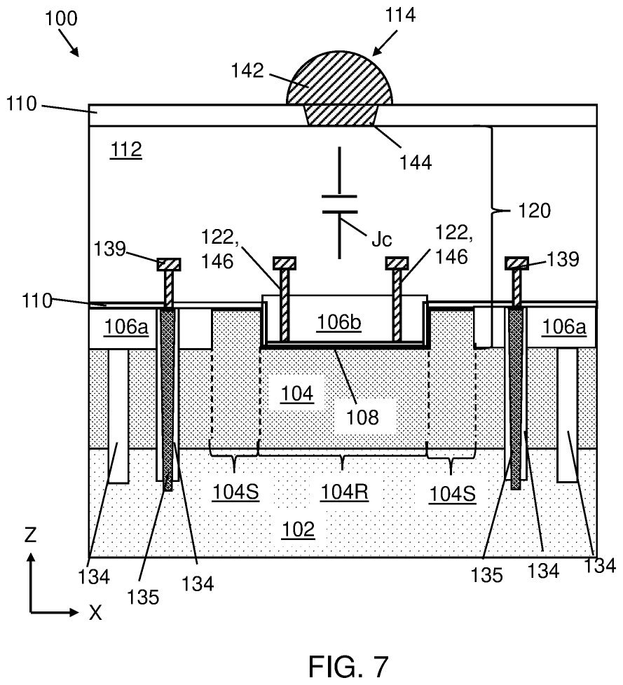

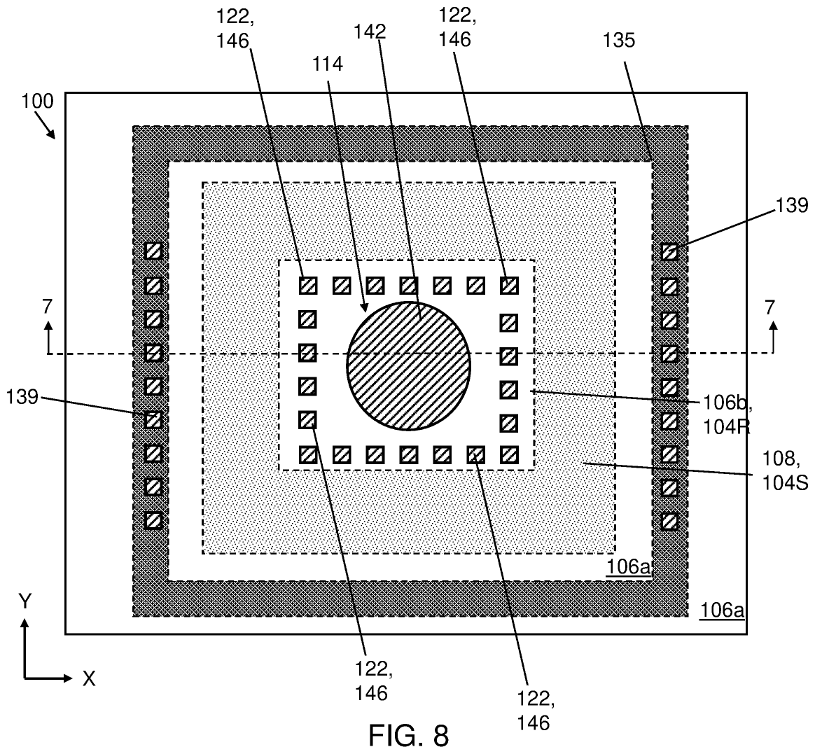

Turning to FIGS. 7 and 8, electrode 114 may take a variety of forms in still further embodiments. For example, electrode 114 may include a solder bump 142 on insulative film 110 for coupling of structure 100 to external components (e.g., a packaging layer or other external structure). Solder bump 142 may be in the form of, e.g., a controlled collapse chip connection (C4) conductive material for connecting external components to a via electrode 144 located within insulative film 110 and on ILD layer 112. The composition of solder bump 142 and via electrode 144 may include any material(s) discussed herein appropriate for use in other implementations of electrode 114. The use of solder bump 142 may allow for external connections to be coupled to capacitive junction Jc without intermediate coupling components (e.g., one or more metal wires, vias, etc.).

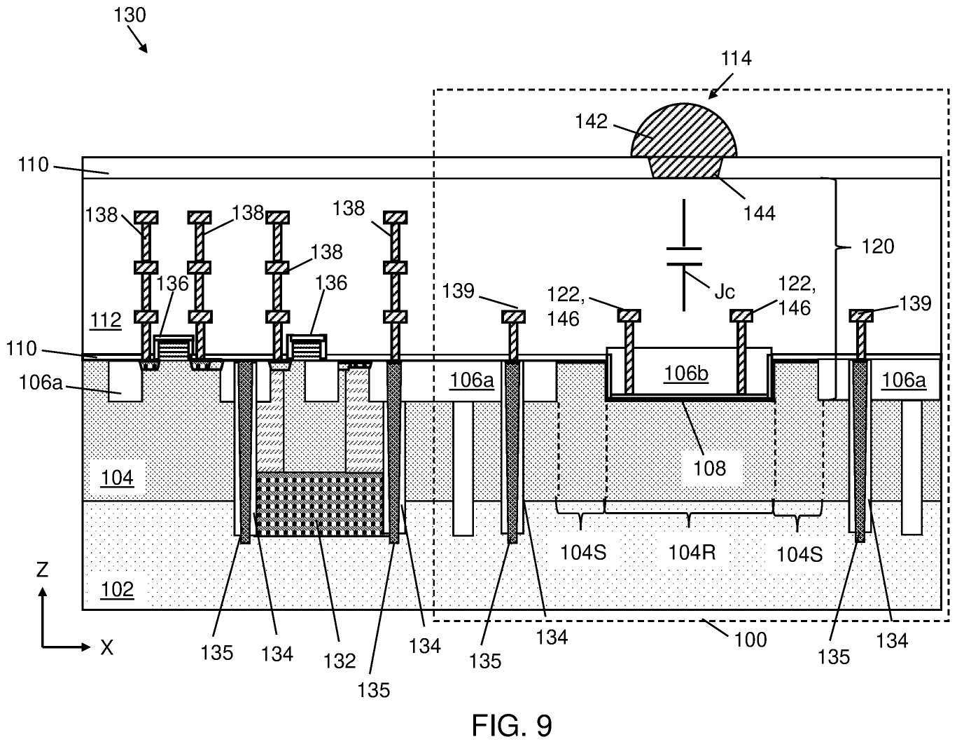

Referring collectively to FIGS. 7-9, structure 100 may include contacts 122 to silicide layer 108 that are not positioned over non-recessed region 104S (FIGS. 7, 8 only) of doped well 104. Here, structure 100 may include contacts 122 in the form of one or more inter-level conductors 146 that extend through TI(s) 106 and are located partially within ILD layer 112 between silicide layer 108 and electrode 114. Inter-level conductors 146 may be on portions of silicide layer 108 that are on recessed region 104R of doped well 104. Inter-level conductors 146 nonetheless may be positioned to surround or otherwise be laterally adjacent the strongest (e.g., centermost) areas of capacitive junction Jc. Inter-level conductors 146 may be coupled to other components and/or devices through wires, vias, etc., not shown but extending into or out of the plane of the page. In still further embodiments, electrode wire(s) 140 (FIGS. 4, 6) may be couple inter-level conductors 146 to active devices 136 (FIG. 9). It is also understood that inter-level conductors 146 may be within ILD layer 112 in embodiments where electrode 114 does not include solder bump 142 and/or via electrode 144. Although DTIs 134, deep terminals 135, and grounding contacts 139 are also shown in FIGS. 7-9, these components also may be omitted.

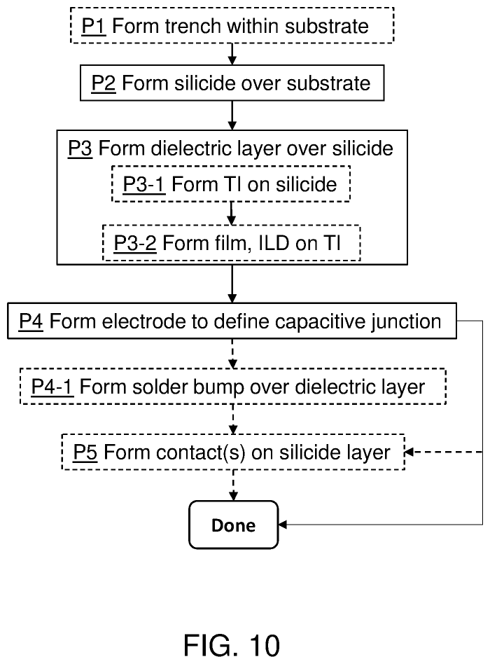

Turning to FIGS. 1, 4, 7, and10, the disclosure also include methods to provide structure 100 according to any embodiment discussed herein. Process P1 may include forming substrate 102 and doped well 104 therein, e.g., by any currently known or later developed doping technique such as implantation, in situ doping, etc. Process P1 also may include forming a recess within substrate 102 and/or doped well 104 to create recessed region 104R and non-recessed region 104S. Process P1 may occur erstwhile to methods of the disclosure (i.e., they may be part of a technique for creating an initial structure), and thus process P1 is indicated with dashed lines in FIG. 10. Methods of the disclosure may include process P2 of forming silicide layer 108 over substrate 102, e.g., by forming a conductive metal on doped well 104, annealing the conductive metal to induce migration of metal ions into doped well 104, and removing excess metal as discussed herein. The forming of silicide layer 108 in process P2 may be simultaneous with the siliciding of other materials in a device. Process P2 thus yields silicide layer(s) 108 operable to provide one electrode for capacitive junction Jc.

Methods of the disclosure may include process P3 of forming dielectric layer 120 over silicide layer 108. In the case where dielectric layer 120 includes multiple insulative materials, process P3-1 of the disclosure may include forming TI(s) 106b on silicide layer 108, as well as any TI(s) 106b for horizontally separating structure 100 from other components on substrate 102. TI(s) 106a, 106b each may be formed by recessing the upper surface of substrate 102 and/or doped well 104 to create recessed regions 104R and non-recessed regions 104S, depositing insulative material(s) to fill recessed region(s) 104R, and planarizing the deposited insulative material(s) to have an upper surface substantially coplanar with the upper surface of non-recessed region(s) 104S. It is emphasized that TI(s) 106b may be differentiated from TI(s) 106a solely by being formed on silicide layer 108. Process P3-2 may include forming insulative film 110 and/or ILD layer 112 over substrate 102 and doped well 104 (and, where applicable, on TI(s) 106b). Insulative film 110 and/or ILD layer 112 may be formed by depositing various dielectric materials according to generally known techniques to form and/or planarize insulative layers. In implementations, other types of dielectric materials may be included in dielectric layer 120, and processes P3-1, P3-2 may be implemented together with various techniques to form such materials or may be omitted entirely.

Methods of the disclosure may include process P4 to form electrode 114 over dielectric layer 120, thus defining capacitive junction Jc across dielectric layer 120. The forming of electrode 114 in process P4 may include forming a portion of ILD layer 112, forming openings and/or trenches in ILD layer 112, depositing a conductive metal over ILD layer 112 (and on insulative film 110 where applicable), and planarizing the conductive metal to define electrode 114. These processes may occur as part of, and/or may be substituted for, damascene or dual damascene to create electrode 114 together with any vias 116 coupled thereto. Thus, Process P4 also may include, e.g., forming vias 116 and/or metal wires 118 in the same metal layer and/or metal layers above electrode 114 for coupling of electrode 114 to other components. Optionally, methods of the disclosure may proceed to process P4-1 of forming solder bump 142 and/or via electrode 144 to provide electrode 114. In still further embodiments, process P4 itself may include process P4-1 (e.g., where solder bump 142 itself is electrode 114). The method may then conclude (“Done”) after capacitive junction Jc is formed within structure 100.

In some implementations, methods of the disclosure may include process P5 of forming contacts 122 and/or inter-level conductors 146 (FIGS. 7, 9) to silicide layer 108. The forming of contacts 122 and/or inter-level conductors 146 may include, e.g., removing a portion of ILD layer 122, forming openings within the remaining portions of ILD layer 112 over non-recessed region 104S or recessed region 104R, re-forming additional portions of ILD layer 112, forming connective wires and/or vias to contacts 122 and/or inter-level conductors 146, and continuing to form ILD layer 112 to a desired height. The forming of contacts 122 and/or inter-level conductors 146 includes forming refractory metal liners (not shown) within the openings and filling any remaining space with conductive material to provide contact(s) 122 and/or inter-level conductors 146. As discussed elsewhere herein, contact(s) 122 and/or inter-level conductors 146 to silicide layer 108 may be laterally adjacent, or may surround, the locations where capacitive junction Jc is strongest. The method then conclude (“Done”) and any remaining processes to form IC structure 130 (FIGS. 3, 6, 9) or a product with IC structure 130 therein may be implemented according to conventional techniques.

Embodiments of the disclosure provide various technical and commercial advantages, examples of which are discussed herein. Among other things, structure 100 may provide compact integration of capacitive coupling or galvanic isolation within an IC structure 130. Structure 100, during operation, may enable passage of AC signals while preventing transmission of DC signals between isolated components. Embodiments of structure 100 may be easily integrated into conventional processes to form various wiring layers over substrate 102 and may be implemented simultaneously with other processes to form silicide materials and/or other elements (e.g., dielectric materials and conductors) of a product. Embodiments of the disclosure, advantageously, may use ILD layer 112 as part of dielectric layer 120 to provide capacitive junction JC. TI(s) 106b also may be included to customize the capacitance across capacitive junction Jc. DTI(s) 134 (FIGS. 4, 5, 7, 8) optionally may be provided to provide still stronger amounts of electrical isolation.

The structure and method as described herein are used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a,” “an,” and “the,” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately,” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A structure comprising:
a silicide layer on a substrate;
a dielectric layer over the substrate and the silicide layer; and
an electrode within a wiring layer on the dielectric layer, wherein the dielectric layer defines a capacitive junction between the silicide layer and the electrode.

2. The structure of claim 1, wherein the silicide layer is on a recessed region of the substrate.

3. The structure of claim 2, wherein the dielectric layer includes:
a trench isolation (TI) on the silicide layer and within the recessed region of the substrate; and
an inter-level dielectric (ILD) vertically between the TI and the electrode.

4. The structure of claim 2, further comprising a plurality of contacts on the silicide layer and over a non-recessed region of the substrate, wherein the plurality of contacts surrounds the recessed region of the substrate.

5. The structure of claim 4, further comprising a trench isolation (TI) within the substrate and surrounding the plurality of contacts.

6. The structure of claim 1, wherein the electrode is coupled to a solder bump within the wiring layer.

7. The structure of claim 1, further comprising:
a deep trench isolation (DTI) horizontally between the silicide layer and an active device on the substrate; and
a grounding contact to the DTI.

8. The structure of claim 1, further comprising an inter-level conductor within the dielectric layer between the silicide layer and the electrode.

9. A structure comprising:
a substrate including a recessed region adjacent a non-recessed region;
a silicide layer within the recessed region of the substrate;
a dielectric layer over the silicide layer, wherein the dielectric layer includes:
a trench isolation (TI) on the silicide layer and within the recessed region of the substrate, and
an inter-level dielectric (ILD) on the TI; and
an electrode within a wiring layer on the dielectric layer, wherein the dielectric layer defines a capacitive junction between the silicide layer and the electrode.

10. The structure of claim 9, further comprising a plurality of contacts on the silicide layer and over the non-recessed region of the substrate, wherein the plurality of contacts surrounds the recessed region of the substrate.

11. The structure of claim 10, further comprising an additional trench isolation (TI) within the substrate and surrounding the plurality of contacts.

12. The structure of claim 9, wherein the electrode is coupled to a solder bump within the wiring layer.

13. The structure of claim 9, further comprising:
a deep trench isolation (DTI) horizontally between the silicide layer and an active device on the substrate; and
a grounding contact to the DTI.

14. The structure of claim 9, further comprising an inter-level conductor within the dielectric layer between the silicide layer and the electrode.

15. A method, comprising:
forming a silicide layer on a substrate;
forming a dielectric layer over the substrate and the silicide layer; and
forming an electrode within a wiring layer on the dielectric layer, wherein the dielectric layer defines a capacitive junction between the silicide layer and the electrode.

16. The method of claim 15, further comprising forming a recessed region within the substrate, wherein the silicide layer is formed within the recessed region of the substrate.

17. The method of claim 16, wherein forming the dielectric layer includes:
forming a trench isolation (TI) on the silicide layer and within the recessed region of the substrate; and
forming an inter-level dielectric (ILD) vertically between the TI and the electrode.

18. The method of claim 16, further comprising forming a plurality of contacts on the silicide layer and over a non-recessed region of the substrate, wherein the plurality of contacts surrounds the recessed region of the substrate.

19. The method of claim 15, wherein forming the electrode includes forming a solder bump over the dielectric layer.

20. The method of claim 15, further comprising forming an inter-level conductor within the dielectric layer between the silicide layer and the electrode.
